(19) United States
(12) Patent Application Publication
(10) Pub. No.: US 2015/0282324 A1
(43) Pub. Date: Oct. 1, 2015

(54) CIRCUIT BODY AND ELECTRONIC COMPONENT UNIT

(71) Applicant: Yazaki Corporation, Tokyo (JP)

(72) Inventors: Koji Miyawaki, Susono-shi (JP); Shouichi Furukawa, Susono-shi (JP)

(21) Appl. No.: 14/667,829

(22) Filed: Mar. 25, 2015

(30) Foreign Application Priority Data
Mar. 27, 2014 (JP) 2014-065380

(51) Int. Cl. H05K 1/18; H05K 1/02

(52) U.S. Cl. CPC H05K 1/181; H05K 1/0284; H05K 2201/10272; H05K 2201/10015; H05K 2201/1003

(57) ABSTRACT

Provided is a circuit body on which a replacement electronic component can be mounted in the same manner as an existing electronic component even if the replacement electronic component has a different shape from the existing electronic component, and is an electronic component unit that includes the circuit body. The circuit body which a sheet metal member includes has a first busbar, a second busbar, and a third busbar. Each of the first busbar, the second busbar, and the third busbar has a plurality of through holes for attaching one of a plurality of leads included in an electronic component connected between the busbar and the other busbar.

### TECHNICAL FIELD

The present invention relates to a circuit body and an electronic component unit.

### DESCRIPTION OF RELATED ART

For example, Japanese Patent Application Laid-Open Publication No. 2013-8457 (Patent Literature 1) discloses an electronic component unit that has a plurality of electronic components and parts. As shown in FIG. 14 of the accompanying drawings, the electronic component unit (denoted at 815 in the drawing) of Japanese Patent Application Laid-Open Publication No. 2013-8457 includes a base member 820 made from an insulation material, and a plurality of busbars 833A-833F secured to the base member 820. The electronic component unit 815 also includes a plurality of electronic components 841A-841E. Leads of the electronic components 841A-841E are connected to predetermined positions of the busbars 833A-833F to configure an electric circuit having a desired function.

### LIST OF PRIOR ART REFERENCES

### Patent Literatures

PATENT LITERATURE 1: Japanese Patent Application Laid-Open Publication No. 2013-8457

### SUMMARY OF THE INVENTION

For example, the above-described electronic component unit has a plurality of electronic components (e.g., capacitors and coils) and is configured to function as a frequency filter that only allows a signal having a predetermined wavelength to pass therethrough. The electronic component unit that is designed to function as the frequency filter should be adjusted to have a filtering property that is suitable for a location on the circuit where the electronic component unit is used. Specifically, the filtering property (frequency range that allows the signal to pass) is adjusted by replacing an existing component with a new electronic component having a different parameter, e.g., different capacitance and/or inductance and a new electronic component having a different function. However, the shape of the electronic component often changes when the parameter or function of the electronic component changes, in particular, the lead interval of the electronic component changes when the parameter or function of the electronic component changes, requiring redesigning of the busbars in accordance with a replacement electronic component. Accordingly, the electronic component unit should be designed for each filtering property, making it difficult to commonly use an electronic member.

An object of the present invention is to address these problems. Namely, it is intended to provide a circuit body in which a new electronic component having a different shape from an existing electronic component is attached in place of the existing electronic component in the same attaching manner as the existing electronic component, and to provide an electronic component unit having such a circuit body.

In order to achieve the above-mentioned object, the first aspect of the present invention provides a circuit body including a plurality of busbars positionally fixed to each other, and at least one of the busbars has a plurality of mounting portions. One of the mounting portions is used to mount a lead among a plurality of leads of an electronic component connected between said one of the busbars and the other of the busbars.

According to the second aspect of the present invention, the electronic component of the circuit body according to the first aspect is selected from a plurality of electronic components having different lead intervals. The electronic components have the different lead intervals because the electronic components have different parameters or functions. The mounting portions are arranged at positions that correspond to the different lead intervals of the electronic components.

According to the third aspect of the present invention, the circuit body of the first or second aspect further includes a connecting part formed integral with these two adjacent busbars for connecting at least a pair of adjacent busbars among the busbars.

In order to achieve the above-mentioned object, the fourth aspect of the present invention provides an electronic component unit including: a circuit body according to any one of the first to third aspects; a resin-molded member having an insulation property, the resin-molded body formed integral with the circuit body; and one or more electronic components connected between the busbars.

In order to achieve the above-mentioned object, the fifth aspect of the present invention provides an electronic component unit including: a circuit body according to the third aspect; a resin-molded member having an insulation property, the resin-molded body formed integral with the circuit body; and one or more electronic components connected between the busbars, wherein the resin-molded member is configured such that the connecting part exposes.

According to the first and fourth aspects of the present invention, at least one busbar among a plurality of busbars has a plurality of mounting portions, one of the mounting portions is used to mount one lead among a plurality of leads of an electronic component, and the electronic component is to be connected between the above-mentioned one busbar and the other of the busbars. Thereby, the plurality of mounting portions is located at different positions in the busbars, and the mounting portions can thus be located such as to differ from the distance from the mounting portion of the other busbars disposed in the other electronic component for allowing the other lead among a plurality of leads disposed in the electronic component to be attached. It follows from this that based on the lead interval of a plurality of leads of the electronic component to be connected to the busbars, an appropriate one of the mounting portions is selected from the busbars, so as to combine with the mounting portion of the other busbar, and thus any one of the plurality of electronic components having different lead intervals may be connected between the busbars. It is, therefore, possible to mount any one of the plurality of electronic components having different shapes in the same manner.

According to the second aspect of the present invention, the electronic component is selected from a plurality of electronic components having different lead intervals, and the electronic components have the different lead intervals because the electronic components have different parameters or functions. Also, the mounting portions are arranged at positions that correspond to the different lead intervals of the electronic components. Thus, though the electronic components have different shapes according to different parameters and/or different functions, and in turn different lead intervals, the mounting portions are arranged corresponding to the different lead intervals of the electronic components to be mounted, and therefore it is possible to mount any one of the electronic components more appropriately.

According to the third and fifth aspects of the present invention, the circuit body includes a connecting part for connecting at least a pair of adjacent busbars among a plurality of busbars, and the connecting part is integral with these adjacent busbars. With such configuration, the connecting part may be left or cut off, depending upon the circuit structure, resulting in either a single bus bar in which the pair of busbars is electrically connected with each other, or respective busbars electrically insulated to each other, which leads to variation of realizable circuit structures.

### BRIEF DESCRIPTION OF THE DRAWINGS

FIG. 1A shows a perspective view of a sheet metal member having a circuit body according to one embodiment of the present invention.

FIG. 1B shows a plan view of the sheet metal member shown in FIG. 1A.

FIG. 2 shows a plan view useful to describe a distance between two through holes, which are used as a pair. FIG. 2 shows three pairs of through holes, and three different distances.

FIG. 3 is a plan view showing a configuration of a modified arrangement to the circuit body shown in FIG. 1A.

FIG. 4A is a perspective view of a sheet metal member having another modified circuit body.

FIG. 4B is a plan view of the circuit body shown in FIG. 4A.

FIG. 5A shows a circuit diagram having the circuit body of FIG. 4A when a connecting part is left in the circuit body.

FIG. 5B is a plan view that schematically illustrates connections between a plurality of busbars of the circuit body and electronic components.

FIG. 6A shows a circuit diagram having the circuit body of FIG. 4A when the connected part is disconnected.

FIG. 6B schematically illustrates connections between the busbars of the circuit body and electronic components.

FIG. 7A is a perspective view of an electronic component unit according to the embodiment of the present invention.

FIG. 7B is another perspective view of the electronic component shown in FIG. 7A when viewed from a different direction.

FIG. 8A is a view useful to describe a process of fabricating a molded body included in the electronic component unit of FIG. 7A.

FIG. 8B is a plan view of the molded body shown in FIG. 8A.

FIG. 9A is a perspective view of the molded body included in the electronic component unit shown in FIG. 7A.

FIG. 9B is a plan view of the molded body shown in FIG. 9A.

FIG. 10A is an exploded perspective view of the electronic component unit shown in FIG. 7A.

FIG. 10B is another perspective view of the electronic component unit of FIG. 10A.

FIG. 11A is a perspective view useful to describe how the electronic component unit of FIG. 7A is received in the housing.

FIG. 11B is another perspective view useful to describe how the electronic component unit of FIG. 7A is received in the housing.

FIG. 12A is a perspective view of a noise filter device that includes the electronic component unit of FIG. 7A.

FIG. 12B is another perspective view of the noise filter device of FIG. 12A.

FIG. 13A is a perspective view of a modification to the electronic component unit shown in FIG. 7A.

FIG. 13B is another perspective view of the modification of FIG. 13A.

FIG. 14 is an exploded perspective view of a conventional electronic component unit.

### DETAILE DESCRIPTION OF THE INVENTION

### Circuit Body and Sheet Metal Member

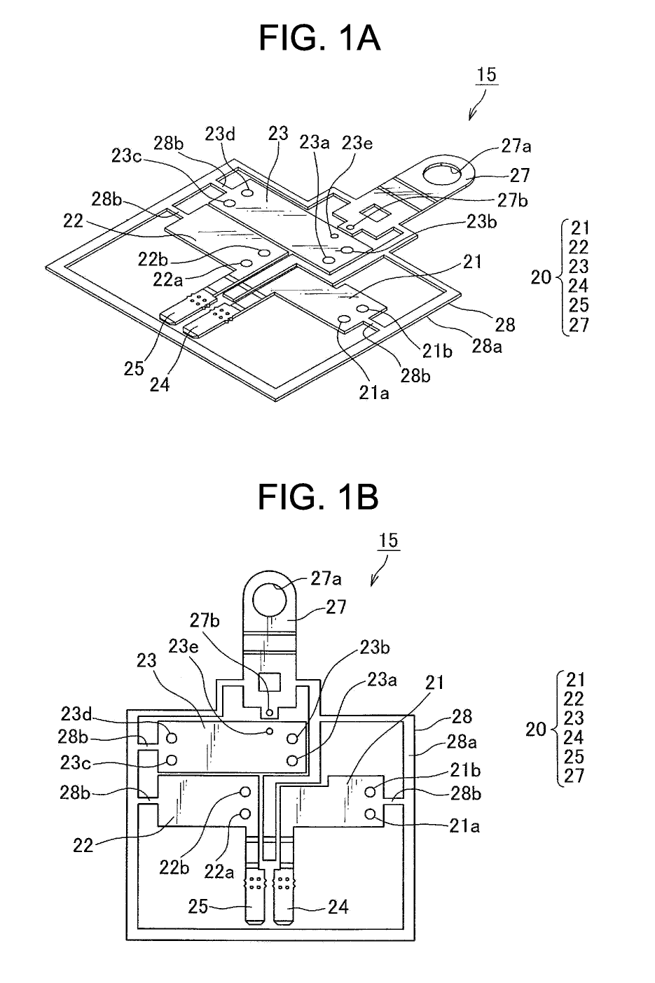

A sheet metal member having a circuit body according to one embodiment of the present invention will be now described with reference to FIGS. 1-6 of the accompanying drawings.

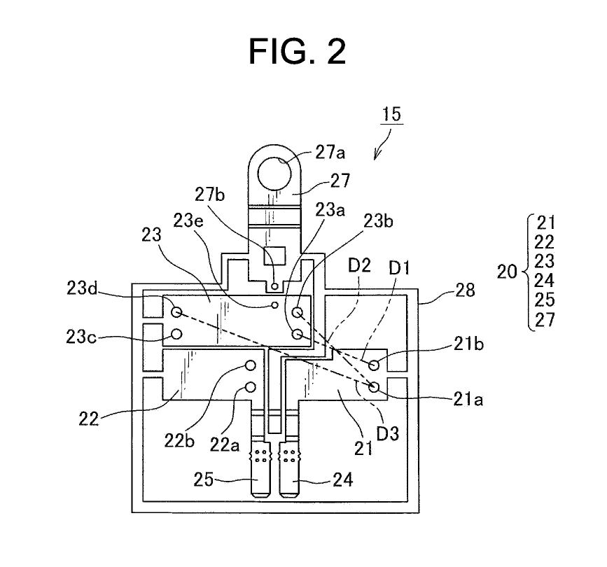

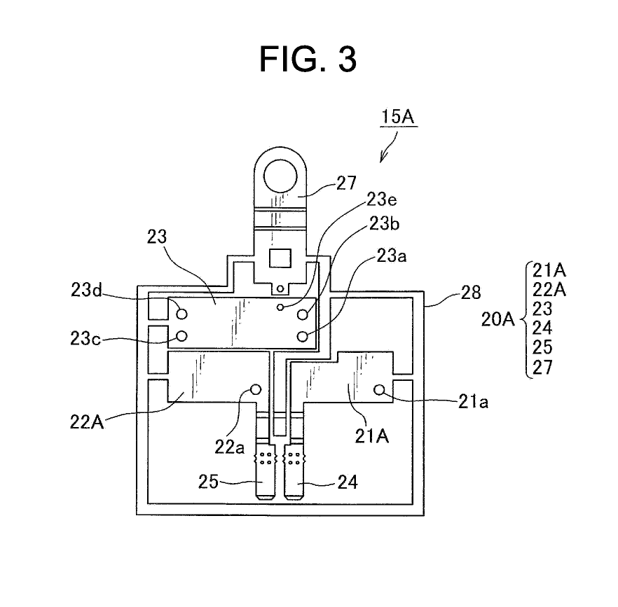

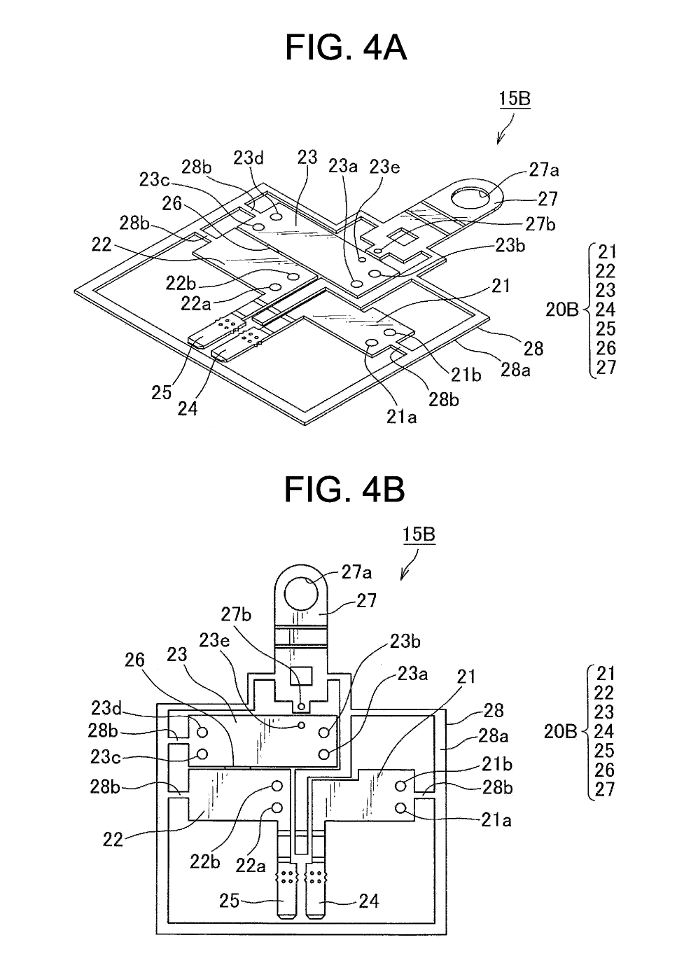

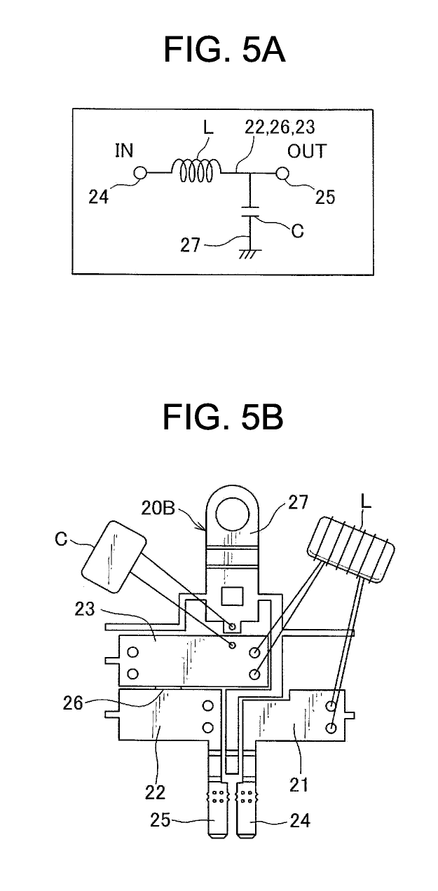

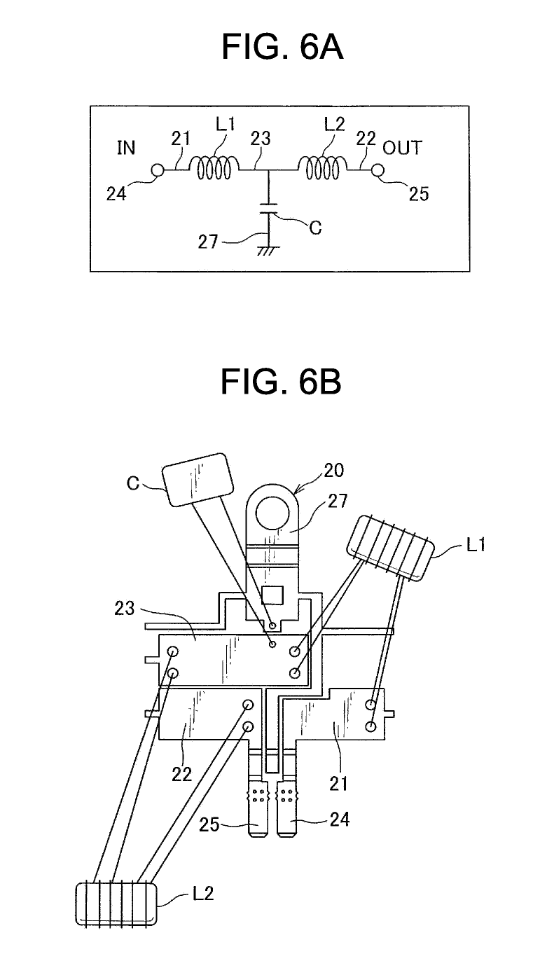

FIGS. 1A and 1B are views that are useful to describe a sheet metal member having a circuit body according to an embodiment of the present invention. Specifically, FIG. 1A shows a perspective view of the sheet metal member and FIG. 1B shows a plan view of the sheet metal member. FIG. 2 shows a plan view useful to describe a distance between two through holes, which are used as a pair. In FIG. 2, there are three pairs of through holes. FIG. 3 shows a plan view showing a configuration of a modified circuit body shown in FIG. 1A. FIGS. 4A and 4B show a configuration of another modification to the circuit body shown in FIG. 1A. Specifically, FIG. 4A is a perspective view of a sheet metal member having the modified circuit body, and FIG. 4B is a plan view. FIGS. 5A and 5B are views useful to describe a circuit configuration that has the circuit body of FIG. 4A, with a connecting part being left in the circuit body. Specifically, FIG. 5A is a circuit diagram, and FIG. 5B is a plan view that schematically illustrates connections between a plurality of busbars of the circuit body and electronic components. FIGS. 6A and 6B are views useful to describe a circuit configuration that has the circuit body of FIG. 4A, with the connected part is being cut off. Specifically, FIG. 6A is a circuit diagram, and FIG. 6B schematically illustrates connections between the busbars of the circuit body and electronic components.

The circuit body of this embodiment is used to fabricate an electronic component unit mentioned below. Specifically, the circuit body has a plurality of busbars, which are connection members to be included in the electronic component unit. The busbars are connected to the electronic components in the electronic component unit, and the busbars and the electronic components constitute in combination a circuit that can perform a certain function. For example, when the busbars and the electronic components constitute a circuit, which serves as a frequency filter that allows a signal having a predetermined wavelength to pass therethrough, the electronic components, e.g., capacitors and coils are connected to the busbars.

The sheet metal member 15 is prepared by, for example, punching a flat plate member (metal plate) having conductivity, such as a copper plate or an aluminum plate, to a predetermined shape. As shown in FIGS. 1A and 1B, the sheet metal member 15 has a circuit body 20 and a frame 28. The circuit body 20 is integral with the frame 28. The circuit body 20 has a plurality of busbars, namely, a first busbar 21, a second busbar 22, and a third busbar 23. The circuit body 20 also has a pair of terminal pieces 24 and 25, and a bracket 27.

Each of the first busbar 21, the second busbar 22, and the third busbar 23 has a generally rectangular (oblong) shape when viewed from the top, and also has a flat plate shape. The first busbar 21, the second busbar 22, and the third busbar 23 are closely arranged with predetermined spacing such that the long sides of the first busbar 21, the second busbar 22, and the third busbar 23 are parallel to each other. The first busbar 21 has through holes 21a and 21b at one thereof in the longitudinal direction (right end in FIG. 1). The through holes 21a and 21b are positioned side by side in the width direction. The through holes 21a and 21b are referred to as a plurality of mounting portions. Similarly, the second busbar 22 has through holes 22a and 22b at one thereof in the longitudinal direction (right end in FIG. 1). The through holes 22a and 22b are positioned side by side in the width direction. The through holes 22a and 22b are also referred to as a plurality of mounting portions. The third busbar 23 has through holes 23a and 23b at one end thereof in the longitudinal direction and another through holes 23c and 23d at the other end thereof. The through holes 23a and 23b are positioned side by side in the width direction, and the through holes 23c and 23d are positioned side by side in the width direction. The through holes 23a, 23b, 23c and 23d are also referred to as a plurality of mounting portions. Also, the third busbar 23 has a through hole 23e at a position that faces the bracket 27 to be mentioned below. Leads of a capacitor 41 and coils 42 and 43 to be mentioned below extend through the through holes of the respective busbars, and the leads are fixedly secured to the associated through holes by soldering.

One terminal piece 24 of the paired two terminal pieces 24 and 25 is provided such that the terminal piece 24 extends in the width direction from the other longitudinal end (left end in FIG. 1) of the first busbar 21. The other terminal piece 25 is provided such that the terminal piece 25 extends from one longitudinal end of the second busbar 22 in the same direction as the terminal pin 24. The terminal pieces 24 and 25 are arranged in parallel to each other with a predetermined gap.

The bracket 27 has a rectangular shape when viewed from the top, and also has a flat plate shape. One end (upper end in FIG. 1) of the bracket 27 has a semicircular shape. This end of the bracket 27 may be referred to as an outer end. A screw hole 27a is formed at the outer end of the bracket 27 such that a not-shown screw or the like can extend through the screw hole 27a. A through hole 27b is formed at the other end of the bracket 27. The bracket 27 is provided such that the inner end of the bracket 27 faces the third busbar 23 with a predetermine gap. The bracket 27 is earthed (connected to the ground) by the screw or the like that extends through the screw hole 27a.

The frame 28 has a frame main body 28a, which has a generally quadrilateral frame shape. The frame main body 28a is arranged to surround the first busbar 21, the second busbar 22, the third busbar 23 and the paired terminal pieces 24 and 25. The first busbar 21, the second busbar 22 and the third busbar 23 are connected to the frame main body 28a by a plurality of connection stems 28b that extend inward from the frame main body 28a. The bracket 27 is connected to one side of the frame main body 28a, and it may be said that the bracket 27 is inserted in the frame main body.

The frame 28 has the frame main body 28a that is connected to the first busbar 21, the second busbar 22 and the third busbar 23 by the connection stems 28b, and therefore the frame 28 fixes the positional relationship among the first busbar 21, the second busbar 22 and the third busbar 23. In other words, the positions of the first busbar 21, the second busbar 22 and the third busbar 23 are fixed by the frame 28 such that the first busbar 21, the second busbar 22 and the third busbar 23 take appropriate positions when the first busbar 21, the second busbar 22 and the third busbar 23 are assembled in an electronic component unit 10 to be mentioned below. The frame 28 are joined and united to the busbars 21, 22, and 23 of the circuit body 20 to determine (fix) the positional relationship among the busbars 21, 22, and 23.

Now, the operation of the circuit body 20 will be described.

The first busbar 21, the second busbar 22, the third busbar 23 and the bracket 27 of the circuit body 20 are separated from the frame 28 when the circuit body 20 is assembled into the electronic component unit 10 to be mentioned below. The electronic components are connected between the busbars and the bracket when the circuit body 20 is assembled into the electronic component unit 10.

The following description deals with an electronic component that spans the first busbar 21 and the third busbar 23. The first busbar 21 has the through holes 21a and 21b to receive one of the leads of the electronic component, and the third busbar 23 has the through holes 23a-23d to receive the other lead of the electronic component. When the electronic component is connected between the first busbar 21 and the third busbar 23, there are, for example, three choices as shown in FIG. 2: (1) the through hole 21b and the through hole 23a are selected, and a distance between the holes 21b and 23a is a distance D1, (2) the through hole 21a and the through hole 23b are selected, and a distance between the holes 21a and 23b is a distance D2, and (3) the through hole 21a and the through hole 23d are selected, and a distance between the holes 21a and 23d is a distance D3. The distances D1-D3 are different from each other (D1<D2<D3).

Thus, one of the through holes 21a and 21b of the first busbar 21 is selected, one of the through holes 23a, 23b, 23c, and 23d of the third busbar 23 is selected, and the two selected through holes are paired depending upon the lead interval of the electronic component concerned. Accordingly, the electronic component can be appropriately disposed between the two selected through holes. This is also true when an electronic component is connected between the second busbar 22 and the third busbar 23.

Suppose that a coil is connected between the first busbar 21 and the third busbar 23. When an inductance of the coil should be changed (i.e., parameter change), or the coil should be replaced with a capacitor (i.e., function change), the total length of the leads of the electronic component that will be connected between the first and third busbars may change. Even in such case, a pair of through holes is appropriately selected from a plurality of through holes such that the selected pair of through holes matches the electronic component. Thus, it is possible to mount the electronic component appropriately.

According to the above-described embodiment, each of the first busbar 21, the second busbar 22 and the third busbar 23 has a plurality of through holes such that one lead of the electronic component is connected to one of the through holes of one busbar, and the other lead of the electronic component is connected to one of the through holes of another busbar when the electronic component is connected between these two busbars. Specifically, the first busbar 21 has the through holes 21a and 21b, the second busbar 22 has the through holes 22a and 22b, and the third busbar 23 has the through holes 23a-23d.

Because of the above-described configuration, each busbar has a plurality of through holes at different positions. Thus, the through holes of one busbar can have different distances to the through holes of another busbar when the electronic component is connected between these two busbars, with one lead of the electronic component being connected to one of the through holes of the above-mentioned one busbar and the other lead of the electronic component being connected to one of the through holes of the above-mentioned another busbar. Based on the lead interval of the electronic component to be connected between these two busbars, an appropriate one of the through holes is selected in the above-mentioned one busbar, and the selected mounting portion is used together with the through hole of the above-mentioned another busbar. Accordingly, any one of a plurality of electronic components having different lead intervals can be connected between these two busbars in the same manner. It is, therefore, possible to mount any one of a plurality of electronic components having different shapes between the two busbars in the same manner. Thus, the circuit body 20 can be used for a plurality of kinds of electronic component units.

The electronic component, e.g., coil or capacitor, to be connected between the first busbar 21 and the second busbar 22, between the first busbar 21 and the third busbar 23, or between the second busbar 22 and the third busbar 23 is the one that is selected from a plurality of electronic components having different lead intervals. These electronic components have different lead intervals from each other because they have different parameters and/or functions. The through holes 21a, 21b, 22a, 22b, and 23a-23d of the busbars 21-23 are arranged at positions to correspond to the different lead intervals of the electronic components. When the electronic components are imparted different functions and parameters, the electronic components often have different shapes and different lead intervals. In this embodiment, the through holes 21a, 21b, 22a, 22b, and 23a-23d of the busbars 21-23 are formed at positions that can cope with such different lead intervals of the expected electronic components. Therefore, it is possible to appropriately attach any one of the electronic components to the circuit body 20 or the metal sheet member 15.

In the above-described embodiment, a plurality of through holes is formed in each of the first busbar 21, the second busbar 22 and the third busbar 23. It should be noted that the present invention is not limited to such configuration. For example, as shown in FIG. 3, a circuit body 20A may include the first busbar 21A that has a sole through hole 21a, the second busbar 22A that has a sole through hole 22a, and a third busbar 23 that has a plurality of through holes 23a-23e. The sheet metal member 15A may include such circuit body 20A. When an electronic component is connected between the first busbar 21A and the third busbar 23 of the circuit body 20A, one of the through holes 23a-23e of the third busbar 23 is selected depending upon the electronic component, and the selected through hole of the third busbar 23 and the through hole 21a of the first busbar 21A are used for connection of the electronic component. This also applies when an electronic component is connected between the second busbar 22A and the third busbar 23 of the circuit body 20A. Accordingly, the object of the invention is achieved when at least one of a plurality of busbars has a plurality of through holes. The circuit body may have an arbitrary structure as long as at least one of a plurality of busbars has a plurality of through holes. A selected one of the through holes formed in one busbar is used with a through hole of another busbar to connect an electronic component between the two busbars.

In the above-described embodiment, the through holes 21a, 21b, 22a, 22b, and 23a-23d (23a-23e) are used as the mounting portions, to which the leads are mounted. The present invention is not limited to such configuration. For example, alternative mounting portions may be provided on the surface of each busbar instead of the through hole(s). These mounting parts may be prepared by surface-treatment. The surface-treatment is performed such that the leads can be attached to the mounting portions on the busbars. The surface-treatment may include removing an oxidized film from the surface of the busbar or making solder joints on the surface of the busbar. The structure of the mounting portions for connection of the electronic component is arbitrary as long as the object of the invention is achieved.

In the above-described embodiment, the second busbar 22 is electrically disconnected from the third busbar 23. The present invention is not limited to such configuration. For example, as shown in FIGS. 4A and 4B, the second busbar 22 and the third busbar 23, which are located adjacent to each other, may be electrically connected to each other by a connecting part. A circuit body 20B shown in FIGS. 4A and 4B has a connecting part 26 between the second busbar 22 and the third busbar 23. The connecting part 26 is integral with the second busbar 22 and the third busbar 23. A sheet metal member 15B includes such circuit body 20B. For example, the connecting part 26 may be thinner than the second busbar 22 and the third busbar 23, or a notch or groove may be formed in the connecting part 26 beforehand. This facilitates the cutting off of the connecting part 26 from the second busbar 22 and the third busbar 23 with a cutting tool such as a cutter.

When a frequency filter is fabricated with the circuit body 20B of the sheet metal member 15B, a resulting circuit may have a configuration shown in, for example, FIG. 5A or FIG. 6A. FIG. 5A illustrates a circuit diagram of the frequency filter, and FIG. 5B is a plan view of the circuit body 20B together with electronic components being connected between the busbars of the circuit body 20B. The circuit body 20B is obtained by removing the frame 28 from the sheet metal member 15B. FIG. 6A illustrates a circuit diagram of the frequency filter, and FIG. 6B is a plan view of the circuit body 20B together with electronic components being connected between the busbars of the circuit body 20B.

When the circuit body 20B employs the circuit structure shown in FIG. 5A, the connecting part 26 is not cut off. The connecting part 26 remains and electrically couples the second busbar 22 to the third busbar 23. As shown in FIG. 5B, a coil L is connected between the first busbar 21 and the third busbar 23, and a capacitor C is connected between the third busbar 23 and the bracket 27.

When the circuit body 20B employs the circuit structure shown in FIG. 6A, the connecting part 26 is cut off. The second busbar 22 is electrically disconnected from the third busbar 23. This is similar to the circuit body 20 of FIG. 1A. As shown in FIG. 6B, a coil L1 is connected between the first busbar 21 and the third busbar 23, another coil L2 is connected between the second busbar 22 and the third busbar 23, and a capacitor C is connected between the third busbar 23 and the bracket 27.

In this manner, the connecting part 26 is left or cut depending upon the circuit structure. Thus, it is possible to use the same circuit body 20B for different kinds of circuit structure.

As described above, when the desired circuit structure needs the connecting part 26 to remain in the circuit body 20B, the second busbar 22 and the third busbar 23 are electrically connected to each other and serve as a single busbar. When the desired circuit structure needs the connecting part 26 to be cut off from the circuit body 20B, the second busbar 22 and the third busbar 23 are electrically insulated from each other and serve as the separate busbars. The circuit body 20B can be used for a larger number of kinds of circuit structures. Thus, the circuit body 20 (20B) can be used commonly to a plurality of kinds of electronic component units.

### Electronic Component Units

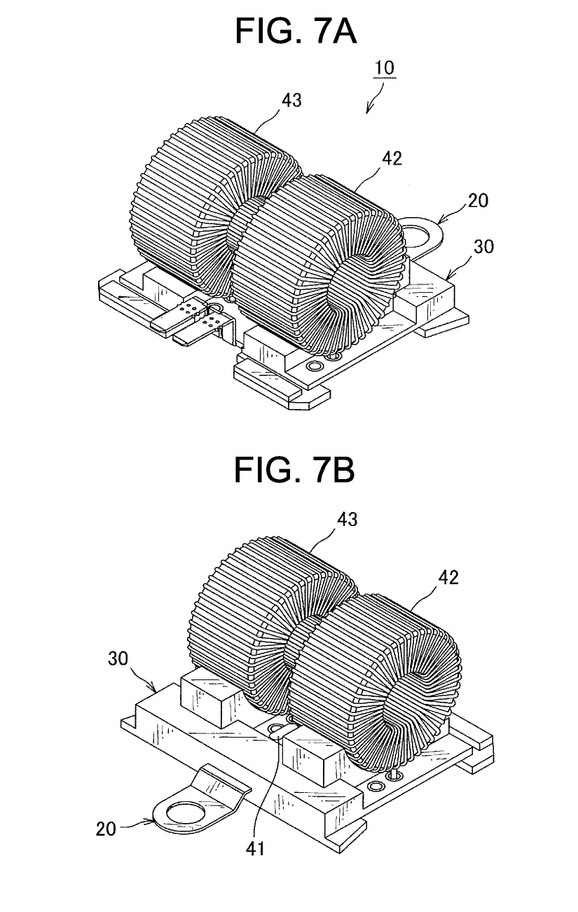

An exemplary electronic component unit 10 according to an embodiment of the invention will be described with reference to FIGS. 7A to 12B.

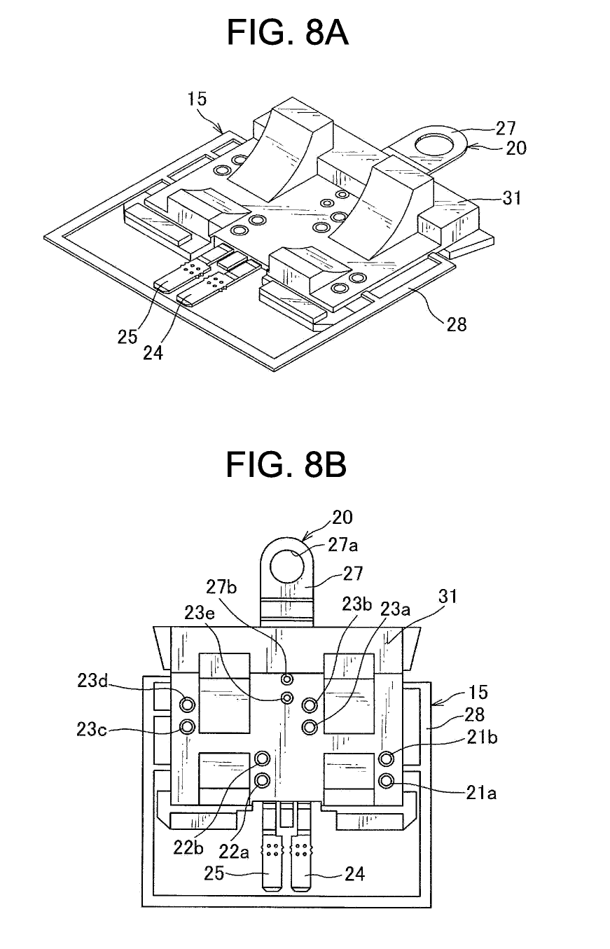

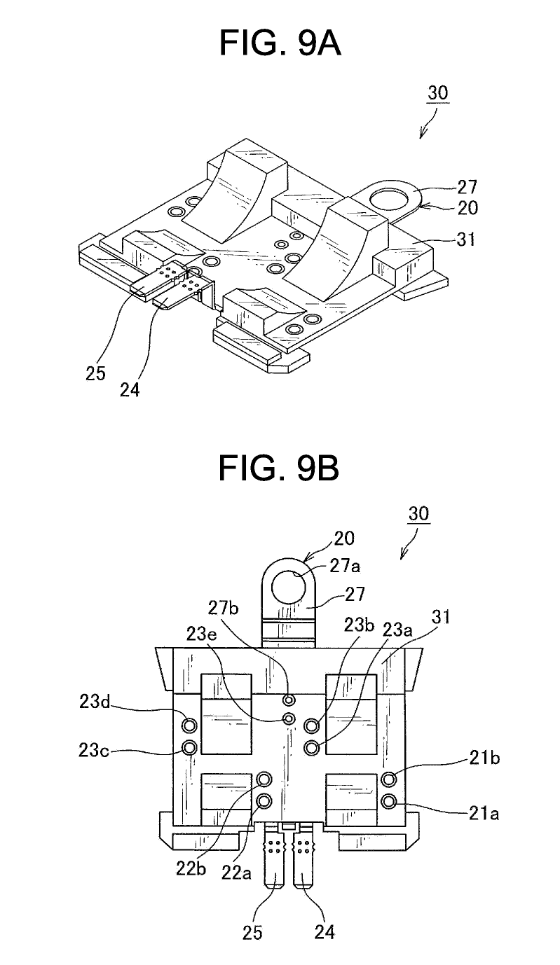

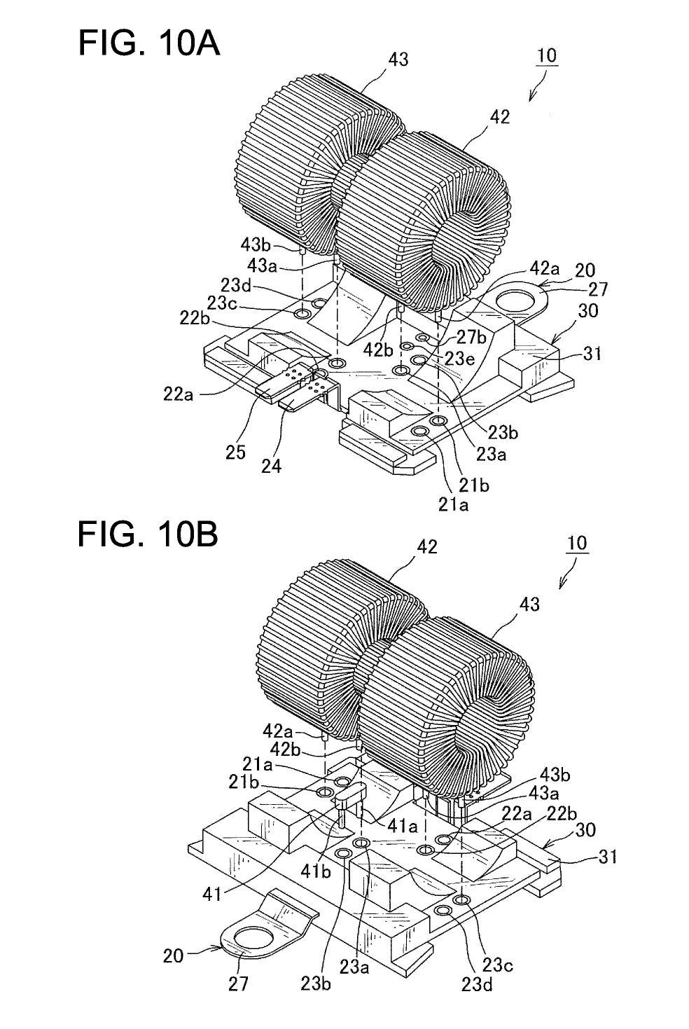

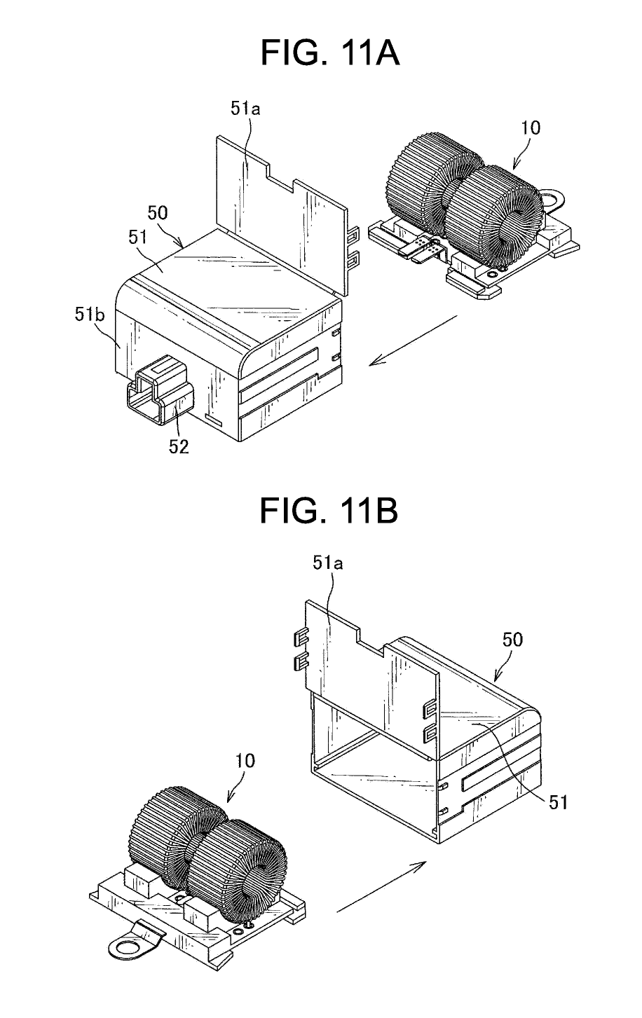

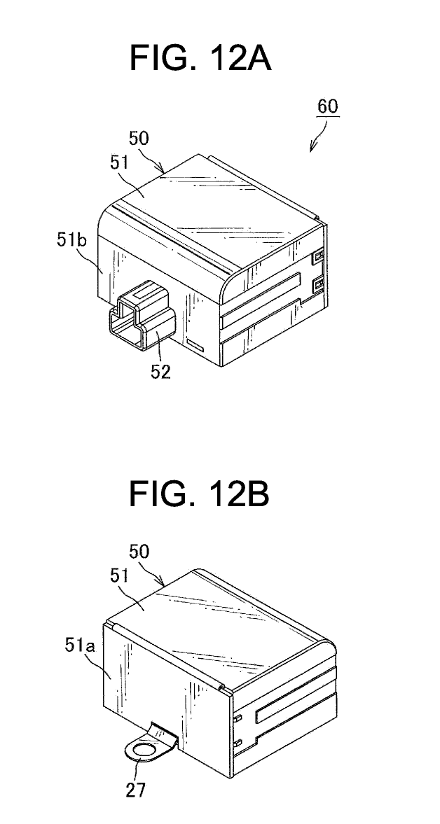

FIG. 7A shows a perspective view of the electronic component unit 10, and FIG. 7B shows another perspective view of the electronic component 10 when viewed from a different direction. FIG. 8A is a view useful to describe a process of fabricating a molded body 30 included in the electronic component unit 10 of FIG. 7A. More specifically, FIG. 8A is a perspective view of the molded body 30 that is obtained when a sheet metal member and a resin-molded member are united by the insert molding. FIG. 8B is a plan view of the molded body 30 shown in FIG. 8A. FIG. 9A is a perspective view of the molded body 30 included in the electronic component unit 10 shown in FIG. 7A, and FIG. 9B is a plan view of the molded body 30 shown in FIG. 9A. FIG. 10A is an exploded perspective view of the electronic component unit 10 shown in FIG. 7A, and FIG. 10B is another perspective view of the electronic component unit 10 of FIG. 10A. FIG. 11A is a perspective view useful to describe how the electronic component unit 10 of FIG. 7A is received in a housing 50, and FIG. 11B is another perspective view showing how the electronic component unit 10 of FIG. 7A is received in the housing 50. FIG. 12A is a perspective view of a noise filter device that includes the electronic component unit 10 of FIG. 7A, and FIG. 12B is another perspective view of the noise filter device of FIG. 12A.

The electronic component unit 10 includes the circuit body 20 of the sheet metal member 15. Electronic components are connected to the busbars of the circuit body 20 to configure a circuitry that has a desired function. In this embodiment, the electronic components include a capacitor 41 and two coils 42 and 43, and the resulting circuitry serves as a frequency filter to allow only a signal having a predetermined frequency to pass therethrough. For example, the electronic component unit 10 has the circuitry shown in FIG. 6A.

As shown in FIGS. 7A and 7B, the electronic component unit 10 includes the molded body 30, the capacitor 41, and the two coils 42 and 43. As mentioned above, the capacitor 41 and the coils 42 and 43 are the electronic components.

The molded body 30 includes the circuit body 20 (i.e., first busbar 21, the second busbar 22, the third busbar 23, a pair of terminal pieces 24 and 25, and the bracket 27), and a resin-molded member 31 (FIG. 8A). The resin-molded member 31 is made from a resin material having an insulation property, such as plastic.

The resin-molded member 31 has a shape of a generally flat plate. The resin-molded member covers (extends over) the first busbar 21, the second busbar 22, the third busbar 23, and the inner end of the bracket 27. The terminal pieces 24 and 25 protrude from the resin-molded member 31, and the outer end of the bracket 27 also protrudes from the resin-molded member 31. The resin-molded member 31 has a configuration that exposes the through holes of the first busbar 21, the second busbar 22, the third busbar 23, and the bracket 27. In this embodiment, the through holes 21a and 21b of the first busbar 21, the through holes 22a and 22b of the second busbar 22, and the through holes 23a-23e of the third busbar 23 are all exposed. Alternatively, the resin-molded member 31 may have a configuration that would only expose those through holes which are used for the leads of the capacitor 41 and the coils 42 and 43. When the circuit body 20B (FIG. 4A) is employed, the resin-molded member 31 may also expose the connecting part 26. With such exposure, it is possible to cut the connecting part 26 later. This increases the freedom of design of the circuit structure. On the surface of the resin-molded member 31, there are formed a plurality of protrusions that fit the shapes of the electronic components to be mounted.

The resin-molded member 31 covers the first busbar 21, the second busbar 22, and the third busbar 23 to fix the positional relationship among the first busbar 21, the second busbar 22, and the third busbar 23. In other words, the positions of the first busbar 21, the second busbar 22, and the third busbar 23 are fixed by the resin-molded member 31 such that the first busbar 21, the second busbar 22, and the third busbar 23 take desired positions in the electronic component unit 10 upon assembling the circuit body 20 into the electronic component unit 10.

The molded body 30 is fabricated in the following manner. Firstly, as shown in FIGS. 8A and 8B, the sheet metal member 15, including the circuit body 20, and the resin-molded member 31 are united by the insert molding. Then, as shown in FIGS. 9A and 9B, that part of the frame 28 of the sheet metal member 15 which protrudes from the resin-molded member 31 is cut off to separate the first busbar 21, the second busbar 22, the third busbar 23, and the bracket 27 from each other. Then, the two terminal pieces 24 and 25 and the bracket 27 are bent to predetermined shapes, respectively, to provide the molded body 30.

The capacitor 41 is, for example, a multi-layer (laminated type) ceramic capacitor or a film capacitor. The capacitor 41 has a pair leads 41a and 41b, as shown in FIG. 10B. One of the leads 41a of the capacitor 41 is received in the through hole 23e of the third busbar 23, and the other lead 41b is received in the through hole 27b of the bracket 27. Thus, the capacitor 41 is connected between the third busbar 23 and the bracket 27.

Each of the coils 42 and 43 has, for example, a toroidal core and an enamel-coated copper wire, which is wound around the toroidal core. The coil 42 has a pair of leads 42a and 42b, and the coil 43 has a pair of leads 43a and 43b. As illustrated in FIG. 10A or FIG. 10B, one lead 42a of the coil 42 is received in the through hole 21b of the first busbar 21, and the other lead 42b is received in the through hole 23a of the third busbar 23. Thus, the coil 42 is connected between the first busbar 21 and the third busbar 23. One of the leads 43a of the coil 43 is received in the through hole 22b of the second busbar 22, and the other lead 43b is received in the through hole 23c of the third busbar 23. Thus, the coil 43 is connected between the second busbar 22 and the third busbar 23.

The electronic component unit 10 itself may be used an independent frequency filter. Alternatively, as shown in FIGS. 11A-11B and FIGS. 12A-12B, the electronic component unit 10 may be placed in the housing 50 to configure a noise filter device 60. The housing 50 has a main body 51, and the main body 51 has an openable wall 51a. The housing 50 also has an engaging part 52 that protrudes from a wall 51b of the main body 51. The wall 51b is opposite the openable wall 51a. As shown in FIG. 11A, the electronic component unit 10 is inserted in the housing 50 from the terminal pieces 24 and 25 side such that the terminal pieces 24 and 25 reach and extend inside the engaging part 52. Thus, the noise filter device 60 (FIG. 12A) can serve as the frequency filter, i.e., noise filter, when the engaging part 52 of the noise filter device 60 engages with a connector of a not-shown separate device.

When the engaging part 52 of the noise filter device 60 engages with the connector of the separate device, the terminal pieces 24 and 25 contact the connector terminals of the separate device for electrical connection to the separate device. Then, the noise filter device 60 is able to function as the frequency filter that only passes a signal having a predetermined frequency, i.e., the noise filter that blocks passage of the signal that does not have the predetermined frequency.

As described above, the electronic component unit 10 of this embodiment includes the circuit body 20 that has the first busbar 21, the second busbar 22, and the third busbar 23. Each of the first busbar 21, the second busbar 22, and the third busbar 23 has a plurality of through holes. Specifically, the first busbar 21 has the through holes 21a and 21b, the second busbar 22 has the through holes 22a and 22b, and the third busbar 23 has the through holes 23a-23d. One of the leads of the electronic component is connected to one of the through holes of one busbar, and the other lead is connected one of the through holes of another busbar, such that the electronic component is connected between these two busbars.

Accordingly, the through holes are formed at different positions on the busbars, and each busbar has a plurality of through holes at different positions. Thus, the through holes of one busbar can have different distances to the through holes of another busbar when the electronic component is connected between these two busbars, with one lead of the electronic component being connected to one of the through holes of the above-mentioned one busbar and the other lead of the electronic component being connected to one of the through holes of the above-mentioned another busbar. Based on the lead interval of the electronic component to be connected between these two busbars, an appropriate one of the through holes is selected in the above-mentioned one busbar, and the selected mounting portion is used together with the through hole of the above-mentioned another busbar. Accordingly, any one of a plurality of electronic components having different lead intervals can be connected between these two busbars in the same manner. Therefore, the circuit body 20 can be used for a plurality of kinds of electronic component units, on which a plurality of electronic components having different shapes are mounted. Because the same circuit body 20 can be used for a variety of the electronic component units, the manufacturing cost can be reduced.

The foregoing has described the preferred embodiments of the present invention. It should be noted that the circuit body and the electronic component unit of the present invention are not limited to such embodiments.

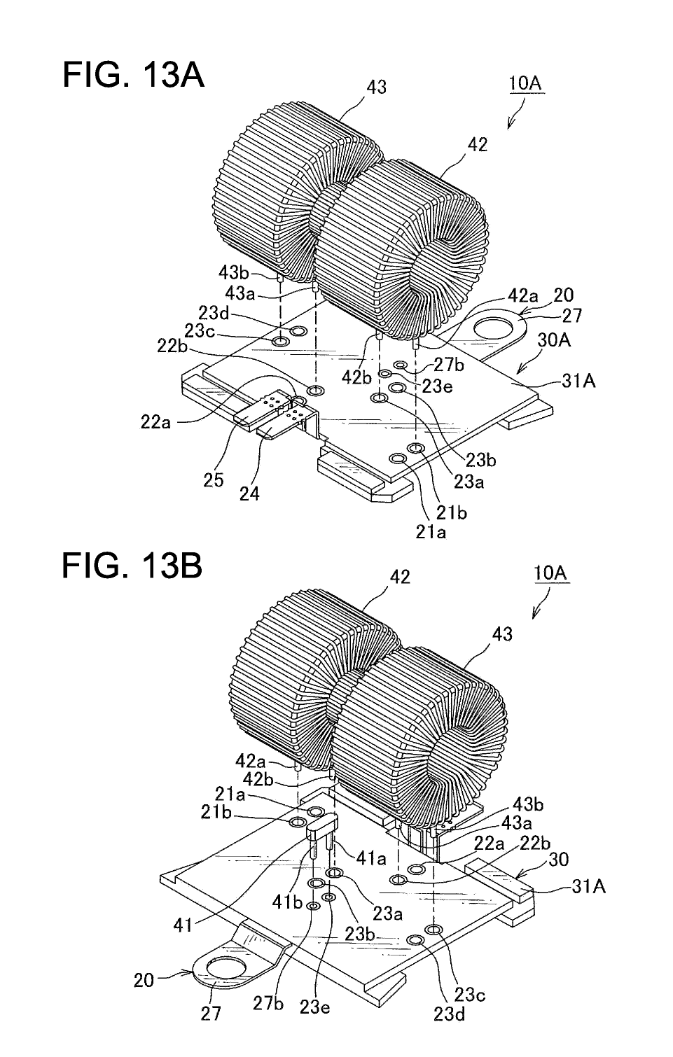

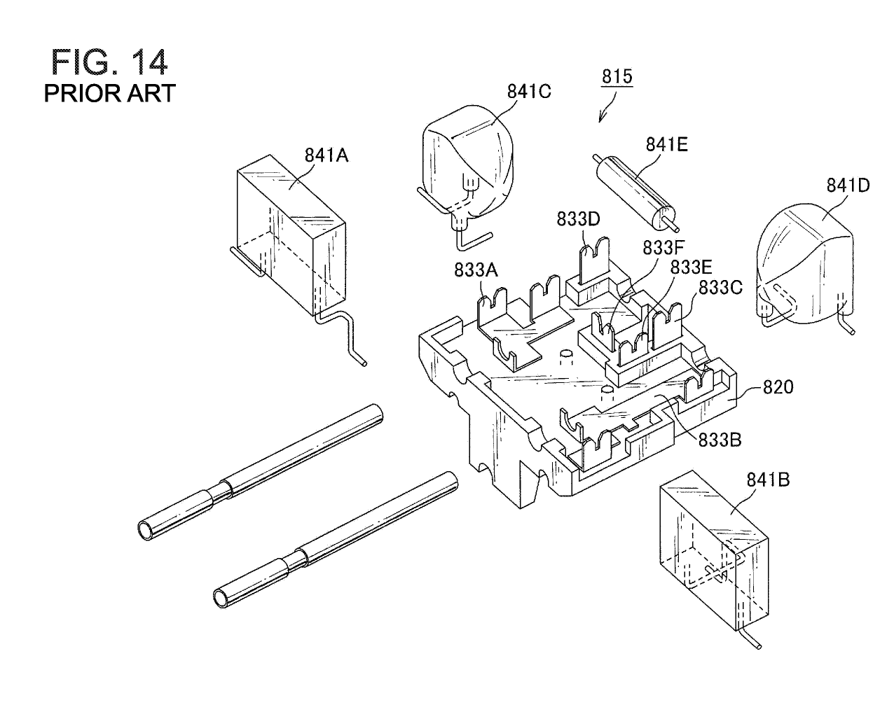

For example, although the electronic component unit 10 of the above-described embodiment has the protrusions on the surface of the resin-molded member 31, which conform with the shapes of the electronic components to be mounted, such protrusions are not always necessary. When the protrusions are provided, the shapes of the electronic components that can be mounted on the molded body 30 are limited to particular shapes. To avoid this, as shown in FIGS. 13A and 13B, a resin-molded member 31A may have a flat surface. A molded body 30A may have such resin-molded member 31A, and an electronic component unit 10A may have the molded body 30A. This configuration can relax the limitations on the shapes of the electronic components to be mounted on the molded body 30A. The molded body 30A can be used for a plurality of electronic component units, on which a plurality of electronic components having different shapes is mounted.

It should be noted that the above-described embodiments merely illustrate exemplary configurations of the present invention, and the present invention is not limited to such embodiments. A person skilled in the art may make various changes and modifications to the above-described embodiments without departing from the spirit and scope of the present invention based on known technologies. Such changes and modifications are also encompassed by the present invention as long as the configuration of the circuit body and/or the configuration of the electronic component unit of the present invention are included.

### REFERENCE SIGNS LIST

10, 10A: Electronic component unit
15, 15A, 15B: Sheet metal member
20, 20A, 20B: Circuit body
21,21A: First busbar
21a, 21b: Through hole (Mounting portion)
22, 22A: Second busbar
22a, 22b: Through hole (Mounting portion)
23: Third busbar
23a-23d: Through hole (Mounting portion)
23e: Through hole
24, 25: Terminal piece
26: Connecting part
27: Bracket
27b: Through hole
28: Frame
30,30A: Molded body
31,31A: Resin-molded member
41: Capacitor
41a, 41b: Lead
42: Coil (Electronic component)
42a, 42b: Lead
43: Coil (Electronic component)
43a, 43b: Lead
50: Housing
60: Noise filter device

What is claimed is:

1. A circuit body comprising:
a plurality of busbars positionally fixed to each other, wherein at least one of the plurality of busbars includes a plurality of mounting portions configured to allow a lead among a plurality of leads to be attached, the plurality of leads being disposed in an electronic component connected between one of the plurality of busbars and the other of the plurality of busbars.

2. The circuit body according to claim 1, wherein the electronic component is selected from a plurality of electronic components having different intervals of the leads based on parameters or functions, and wherein the plurality of mounting portions is arranged to correspond to the different lead intervals of the plurality of electronic components.

3. The circuit body according to claim 1 further comprising a connecting part for connecting at least one pair of adjacent busbars among the plurality of busbars, the connecting part being provided integral with the at least one pair of adjacent busbars.

4. The circuit body according to claim 2 further comprising a connecting part for connecting at least one pair of adjacent busbars among the plurality of busbars, the connecting part being provided integral with the at least one pair of adjacent busbars.

5. An electronic component unit comprising:
the circuit body according to claim 1;
a resin-molded member having an insulation property, and provided integral with the circuit body; and
one or more electronic components connected between the plurality of busbars.

6. An electronic component unit comprising:
the circuit body according to claim 2;
a resin-molded member having an insulation property, and provided integral with the circuit body; and
one or more electronic components connected between the plurality of busbars.

7. An electronic component unit comprising:
the circuit body according to claim 3;
a resin-molded member having an insulation property, and provided integral with the circuit body; and
one or more electronic components connected between the plurality of busbars.

8. An electronic component unit comprising:
the circuit body according to claim 4;
a resin-molded member having an insulation property, and provided integral with the circuit body; and
one or more electronic components connected between the plurality of busbars.

9. An electronic component unit comprising:
the circuit body according to claim 3;
a resin-molded member having an insulation property, and provided integral with the circuit body; and
one or more electronic components connected between the plurality of busbars,
wherein the resin-molded member is formed to have the connecting part expose.

10. An electronic component unit comprising:
the circuit body according to claim 4;
a resin-molded member having an insulation property, and provided integral with the circuit body; and
one or more electronic components connected between the plurality of busbars,
wherein the resin-molded member is formed to have the connecting part expose.
